(19) United States
(12) Patent Application Publication
(10) Pub. No.: US 2008/0276984 A1
(43) Pub. Date: Nov. 13, 2008

(54) System and Method for Magnetically Attaching Photovoltaic Modules Enabling Enhanced Redeployment

(76) Inventor: Michael Gumm, Largo, FL (US)

Correspondence Address: PATWRITE LLC, 408 W. MAIN ST., MARSHALLTOWN, IA, 50158-5759, US

(21) Appl. No.: 12/119,252

(22) Filed: May 12, 2008

Related U.S. Application Data
(60) Provisional application No. 60/928,839, filed on May 11, 2007.

(51) Int. Cl. H01L 31/048; E04D 3/36; E04D 13/18

(52) U.S. Cl. 136/251; 52/173.3

(57) ABSTRACT

A system and method for magnetically attaching photovoltaic modules enabling enhanced redeployment comprises at least one photovoltaic module with a magnetic membrane disposed on an opposite surface to its light receptive side. The module is removeably attachable by the magnetic force of attraction between it and a magnetically receptive substrate. In one embodiment, an insert is applied between the module and the substrate to enhance performance. Inserts include insulative, metallic foils, fabrics, textiles, polymer films, polymer support mounts and air-seals such as silicon caulk. If the substrate is magnetically receptive, the photovoltaic module is applied directly therein. If the substrate is non-magnetic, a magnetically receptive sheet is applied to the substrate. The magnetically receptive sheet may be applied using a self adhesive. In another embodiment, a low surface energy tape is applied to the perimeter providing additional support and to keep elements such as wind and rain from infiltrating.

### RELATED APPLICATIONS

This application claims priority and herein incorporates by reference U.S. provisional patent application 60/928,839, filed May 11, 2007.

### BACKGROUND OF THE INVENTION

There are a number of methods for installing photovoltaic devices on roofs, walls and other surfaces. Installation methods include frame and rack arrays or post mounted systems using rigid panels of crystalline-based silicon, Copper Indium Selenide (CIS), Copper Indium Gallium Selenide (CIGS), or amorphous silicon based photovoltaic modules. These rigid panels systems can be ground-based, wall mounted or roof mounted array systems. Several existing installation methods for the newer flexible thin film photovoltaic modules include laminating flexible thin film modules to single-ply membrane roofs, applying thin film photovoltaic modules with elastomeric coatings to any surface, mechanical attachment, hook and loop attachment and adhering thin film photovoltaic modules to metal roof panels with pressure sensitive adhesives.

Another method referenced in U.S. Pat. No. 5,409,549 issued Apr. 25, 1995 uses brackets and other forms of mechanical attachment as the primary method of attachment with an auxiliary fixation system using magnets, double sided tape or resin adhesives to metal roofs. Traditional installation methods are generally considered permanent and removal of the photovoltaic system is both difficult and expensive.

Photovoltaic solar powered modules and arrays are expensive to purchase and install, yet are capable of generating electricity for 25 to 30-years. Recently a need to re-deploy photovoltaic arrays from the original installation location to a new location has arisen. Some commercial owners and most government, schools and non-profit institutions lease their photovoltaic arrays from solar developers and financial institutions. Solar developers and financial institutions use tax rebates, accelerated depreciations, state and utility rebates with the monthly lease payment to recover the investment cost and make a profit. Other solar developers and investment organizations sell Power Purchase Agreements.

The Power Purchase Agreement owners set up a solar powered array on the user's property and sell the electrical energy to the property owner for a set rate over a period over time, typically ten to twenty years. The Power Purchase Agreement owners acting as a private utility company use tax credits, rebates and the monthly payments for energy cost to recover their investment and make a profit. Leases and Power Purchase Agreements last for a fixed amount of time. There is always the possibility the existing contract will not be renewed or extended. In other cases, lessees or property owner can move, go out of business and not be able to complete the contract terms of the lease or the Power Purchase Agreement.

Used photovoltaic arrays still have residual value as long as the photovoltaic modules are capable of producing electricity. There is a commercial need for an existing photovoltaic array system installation that can easily be disassembled, transported to a new location and then placed back into service under a new contract.

### SUMMARY OF THE INVENTION

A system and method for magnetically attaching photovoltaic modules enabling enhanced redeployment comprises at least one photovoltaic module with a magnetic membrane disposed on an opposite surface to its light receptive side. The module is removeably attachable by the magnetic force of attraction between it and a magnetically receptive substrate. In one embodiment, an insert is applied between the module and the substrate to enhance performance. Inserts include insulative, metallic foils, fabrics, textiles, polymer films, polymer support mounts and air-seals such as silicon caulk. If the substrate is magnetically receptive, the photovoltaic module is applied directly therein. If the substrate is non-magnetic, a magnetically receptive sheet is applied to the substrate. The magnetically receptive sheet may be applied using a self adhesive. In another embodiment, a low surface energy tape is applied to the perimeter providing additional support and to keep elements such as wind and rain from infiltrating.

Other features and advantages of the instant invention will become apparent from the following description of the invention which refers to the accompanying drawings.

### BRIEF DESCRIPTION OF THE DRAWINGS

FIG. 1 is a cross sectional drawing of a photovoltaic module system enabling enhanced redeployment according to an embodiment of the present invention.

FIG. 2 is a cross sectional drawing of a photovoltaic module system enabling enhanced redeployment according to an embodiment of the present invention.

FIG. 3 is a cross sectional drawing of a photovoltaic module system enabling enhanced redeployment according to an embodiment of the present invention.

FIG. 4 is a cross sectional drawing of a photovoltaic module system enabling enhanced redeployment according to an embodiment of the present invention.

FIG. 5 is a cross sectional drawing of a photovoltaic module system enabling enhanced redeployment according to an embodiment of the present invention.

FIG. 6 is a cross sectional drawing of a photovoltaic module system enabling enhanced redeployment according to an embodiment of the present invention.

FIG. 7 is a cross sectional drawing of a photovoltaic module system enabling enhanced redeployment according to an embodiment of the present invention.

FIG. 8 is a cross sectional drawing of a photovoltaic module system enabling enhanced redeployment according to an embodiment of the present invention.

FIG. 9 is a cross sectional drawing of a photovoltaic module system enabling enhanced redeployment according to an embodiment of the present invention.

FIG. 10 is a cross sectional drawing of a photovoltaic module system enabling enhanced redeployment according to an embodiment of the present invention.

FIG. 11 is a cross sectional drawing of a photovoltaic module system enabling enhanced redeployment according to an embodiment of the present invention.

FIG. 12 is a cross sectional drawing of a photovoltaic module system enabling enhanced redeployment according to an embodiment of the present invention.

FIG. 13 is a cross sectional drawing of a photovoltaic module system enabling enhanced redeployment according to an embodiment of the present invention.

FIG. 14 is a cross sectional drawing of a photovoltaic module system enabling enhanced redeployment according to an embodiment of the present invention.

FIG. 15 is a cross sectional drawing of a photovoltaic module system enabling enhanced redeployment according to an embodiment of the present invention.

### DETAILED DESCRIPTION OF THE INVENTION

In the following detailed description of the invention, reference is made to the drawings in which reference numerals refer to like elements, and which are intended to show by way of illustration specific embodiments in which the invention may be practiced. It is understood that other embodiments may be utilized and that structural changes may be made without departing from the scope and spirit of the invention.

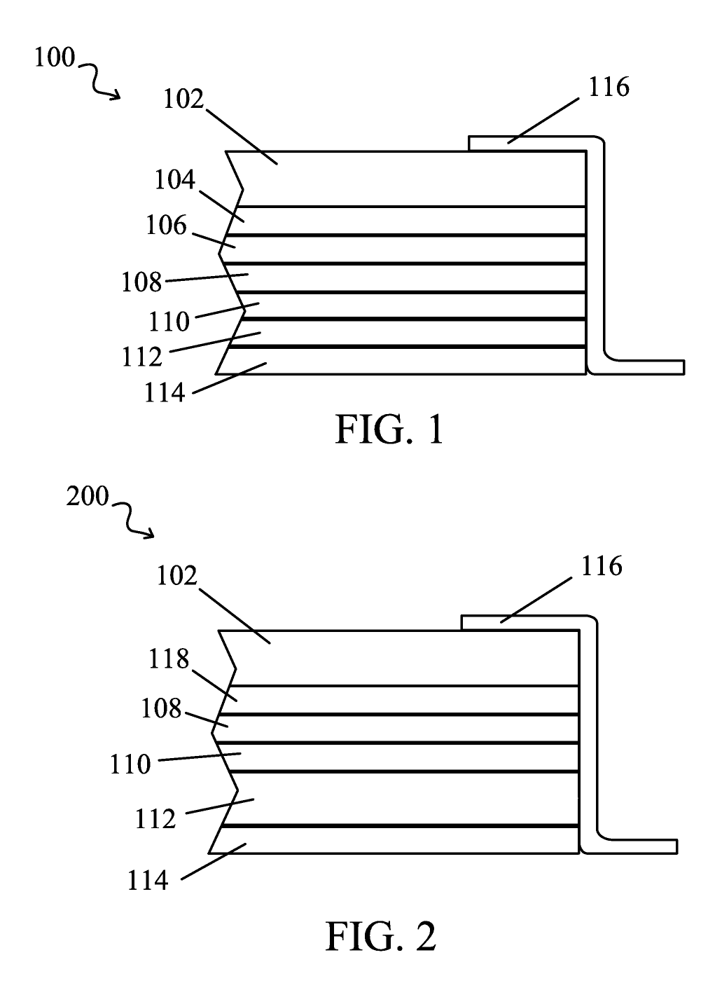

Referring to FIG. 1, a system for magnetically attaching photovoltaic modules enabling enhanced redeployment 100 is shown having a photovoltaic module 102 with a standard back surface 104. A pressure sensitive adhesive 106 is used to attach an insert 108. Insert 108 is an inter-ply construction element that is made of a flexible or rigid polymer having a magnetically enabled surface 110. Magnetically enabled surface 110 is a steel foil. Of course insert 108 may be made of other suitable materials such as insulative materials including closed-cell extruded polystyrene, mineral materials (rock wool, synthetic fibers) or other materials selected to enhance a specific use. Insert 108 may be a single panel, flexible or fan-fold construction as appropriate to a specific use. Insert 108 may also be a metallic foil such as stainless steel or polyvinylidene fluoride (PVDF) painted steel foil. Additionally, insert 108 may be used to add structural support and may be made of fabrics such as synthetic woven or scrim composite fabrics whose weight, density, composite, material composition and or thickness are selected as appropriate to specific uses.

Insert 108 may also be made of a polymer film such as a polymeric or mineral based flexible film. The thickness may be varied to match specific uses. Additionally, the film may be reinforced with polyester of fiber scrim or fabric.

Flexible or rigid polymer based mounted support elements may also be used to form a flat substrate for direct application to a roof or other application substrate. The mounted supports may be solid or may be made with openings to provide airflow to enhance cooling of the modules 102 and application substrate.

A magnetic membrane 112 is used to removeably attach photovoltaic module 102 with associated insert 108 to a magnetically receptive application substrate (not shown). Magnetic membrane 112 has a magnetic surface 114 that contacts the application substrate.

For enhanced attachment, a low surface energy tape 116 is used which keeps air, water and other environmental hazards from entering any spaces between the system 100 and the application substrate. Additionally, use of tape 116 improves wind damage resistance. When removal of system 100 is desired, tape 116 is cut and modules 102 along with associated inserts 108 are removed and prepared for redeployment.

With reference to FIG. 2, a system for magnetically attaching photovoltaic modules enabling enhanced redeployment 200 is shown having photovoltaic module 102 with a back surface with adhesive 118 to adhere module 102 to insert 108. As discussed above, insert 108 is an inter-ply construction element that is made of a flexible or rigid polymer having a magnetically enabled surface 110. Again, magnetic membrane 112 with magnetic surface 114 makes contact with the application substrate. As discussed above, enhanced attachment may be provided using low surface energy tape 116.

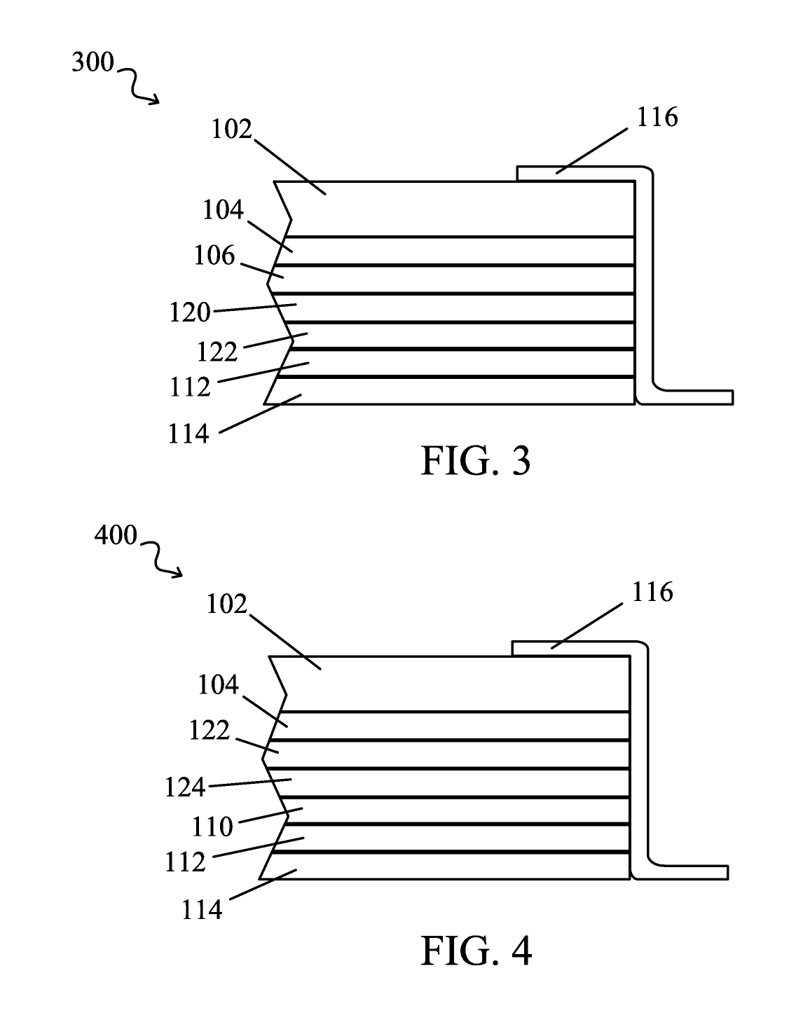

Now referring to FIG. 3, a system for magnetically attaching photovoltaic modules enabling enhanced redeployment 300 is shown having photovoltaic module 102 with standard back surface 104. Layer 106 of pressure sensitive adhesive is used to adhere to an insert 120. Another layer 122 of pressure sensitive adhesive is used to adhere magnetic membrane 112 having magnetic surface 114 which magnetically adheres to the magnetically receptive application substrate (not shown). Again, tape 116 may be used to enhance the installation.

With reference to FIG. 4, a system for magnetically attaching photovoltaic modules enabling enhanced redeployment 400 is shown having photovoltaic module 102 with standard back surface 104. Layer 122 of pressure sensitive adhesive is used to adhere to an insulative insert 124 which also has magnetically enabled surface 110 disposed therein. Magnetic membrane 112 adheres to surface 110 by magnetic force and magnetic surface 114 magnetically adheres to the magnetically receptive application substrate (not shown). Again, tape 116 may be used to enhance the installation.

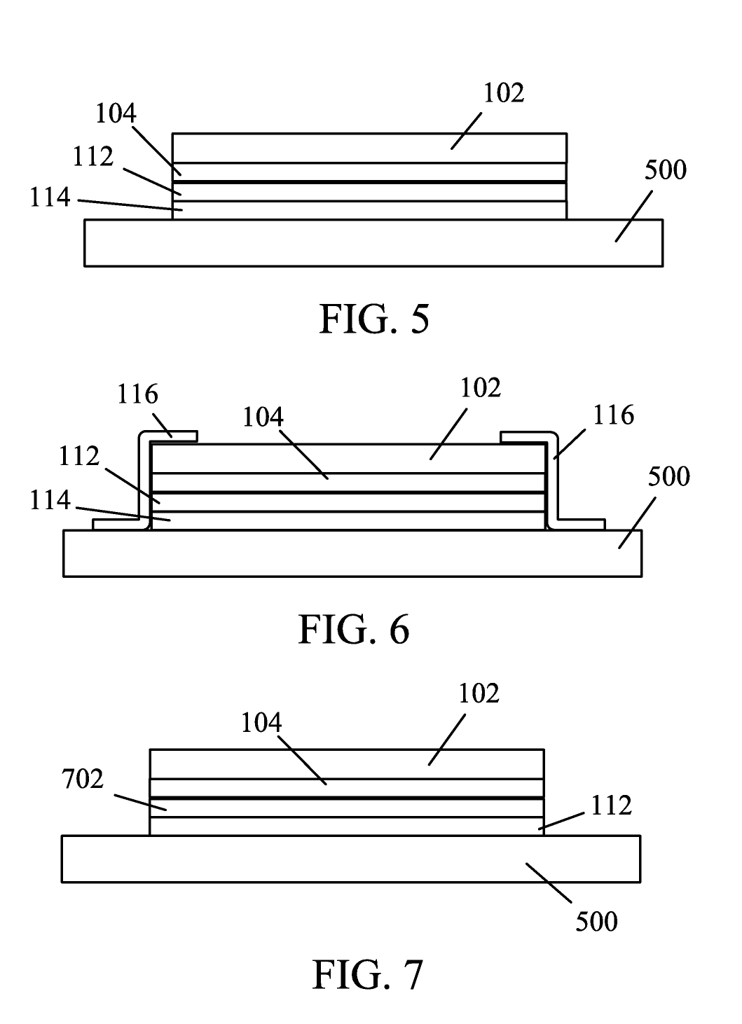

Now referring to FIG. 5, photovoltaic module 102 with standard back surface 104 is joined to magnetic membrane 114 using an appropriate adhesive. Magnetic membrane is attracted to and held in place by the magnetic force between a magnetically receptive application substrate 500. This enables the module 102 to be redeployed with ease.

FIG. 6 illustrates the module of FIG. 5 with the addition of tape 116 to enhance the installation. While still redeployable, the addition of tape 116 gives the installation an illusion of permanence as well as enhancing overall weather resistance.

Referring now to FIG. 7, photovoltaic module 102 with standard back surface 104 is shown having a pressure sensitive adhesive layer 702 joining magnetic membrane 112. Again, the magnetic force is used to removeably attach the system to magnetically receptive application substrate 500.

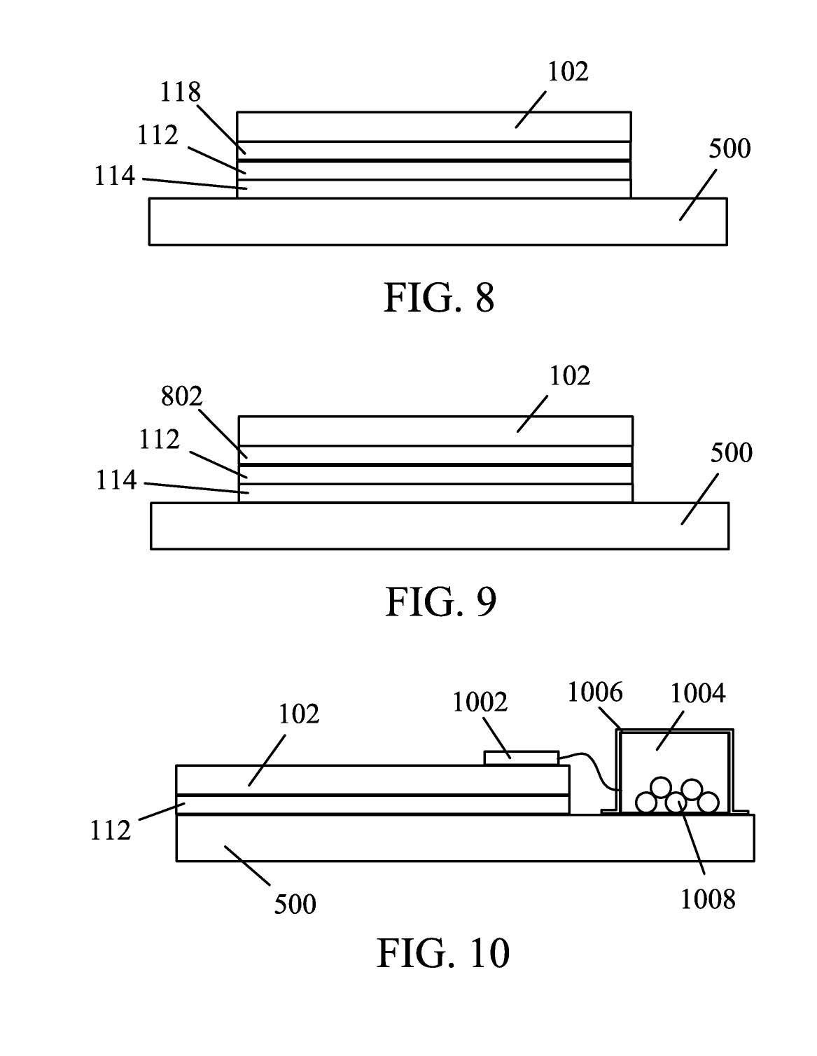

With reference to FIG. 8, photovoltaic module 102 is shown having back surface with adhesive 118 to adhere magnetic membrane 112. Magnetic membrane surface 114 magnetically adheres to magnetically receptive application substrate 500.

Now referring to FIG. 9, photovoltaic module 102 is shown having a back surface with a metallic foil 118. Magnetic membrane 112 magnetically attaches module 102 as well as magnetically receptive application substrate 500.

FIG. 10 illustrates photovoltaic module 102 with associated control and balance circuitry and wiring. A bus 1002 is operatively connected to module 102 which in turn operatively connected to a surface mounted raceway system 1006. Wiring 1008 is used to direct power produced by module 102 to appropriate regulating system (not shown) as is known in the art. A raceway space 1004 provides protection for wiring 1008 and other associated circuitry. Raceway 1006 may be magnetically attached to application substrate 500 as well to enhance redeployment.

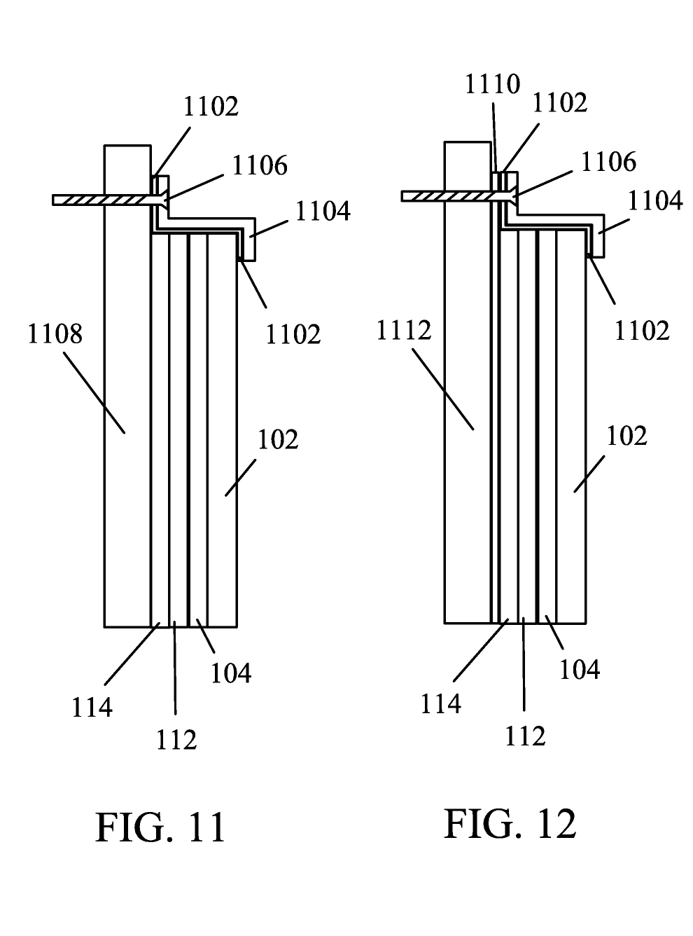

Now referring to FIG. 11, a vertically mounted photovoltaic module 102 is shown having a standard back surface 104 adhered to magnetic membrane 112 with magnetic membrane surface magnetically adhered to a vertical magnetically receptive application substrate 1108. Of course, the system may be used with an application substrate at other angles as well such as a tapering wall or architectural detail. To enhance the installation, a flashing component 1104 is used in combination with the magnetic force since non-horizontal applications put more demands on the adhesive power of the magnetic force due to a component of the gravitational force also acting on the system. A bottom flashing component (not shown) is also used. A fastener 1104 is used to hold flashing component 1104 in place. A gasket or sealant 1102 is used to keep the elements such as rain, snow and wind from penetrating beneath the system.

In FIG. 12, the addition of a metallic foil 1110 having an adhesive surface is used to prepare a non-magnetic application substrate 1112 to magnetically adhere the system.

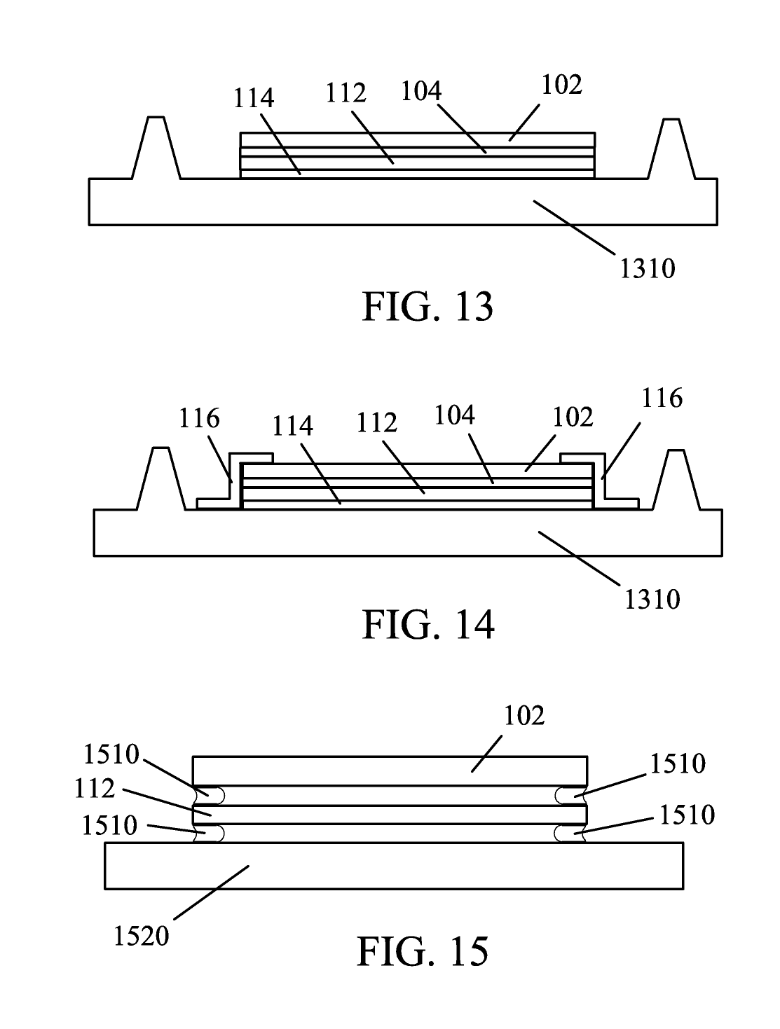

Referring now to FIG. 13, photovoltaic module 102 having a standard back 104 is adhered to magnetic membrane 112 using an appropriate adhesive. Magnetic membrane surface 114 is magnetically adhered to a standing seam substrate 1310 such as a metal roof or the like. FIG. 14 shows the addition of tape 116 to enhance the installation as discussed above.

Additionally, although embodiments shown are typical, not every embodiment is shown in the figures. It is understood that a metallic foil layer could be used to adhere the system to any surface that is not magnetically receptive as shown in only some of the figures. Also, additional inserts could be added without departing from the spirit of the invention and are considered to be included in this description. For example, a fabric structural layer could be added to another insulative layer.

Referring to FIG. 15, photovoltaic module 102 is joined to magnetic membrane 112 with an air seal 1510 such as silicon caulk or other appropriate sealing material as long as the sealant is easily removed. The magnetic force adheres the system to a magnetically receptive application substrate 1520. Again as discussed above, if the surface is not magnetically receptive, a magnetic membrane may be applied to the substrate to provide the necessary magnetically receptive surface.

Although the instant invention has been described in relation to particular embodiments thereof, many other variations and modifications and other uses will become apparent to those skilled in the art.

What is claimed is:

1. A system for magnetically attaching photovoltaic modules enabling enhanced redeployment comprising:
a photovoltaic module having a first and second surface;
said first surface being adapted to receive electromagnetic radiation; and
a magnetic membrane disposed co-planar with said second surface of said photovoltaic module wherein said photovoltaic module is removeably held in place at least partially by a magnetic attraction between said magnetic membrane and a magnetically receptive surface.

2. The system for magnetically attaching photovoltaic modules enabling enhanced redeployment according to claim 1, further comprising an insert disposed between said photovoltaic module and said magnetic membrane.

3. The system for magnetically attaching photovoltaic modules enabling enhanced redeployment according to claim 2 wherein said insert is an insulative insert.

4. The system for magnetically attaching photovoltaic modules enabling enhanced redeployment according to claim 1 further comprising a magnetically receptive sheet disposed on a substrate wherein said magnetically receptive surface is created.

5. The system for magnetically attaching photovoltaic modules enabling enhanced redeployment according to claim 2 wherein said insert is a structural insert.

6. The system for magnetically attaching photovoltaic modules enabling enhanced redeployment according to claim 5 wherein said structural insert is a fabric support insert.

7. The system for magnetically attaching photovoltaic modules enabling enhanced redeployment according to claim 5 wherein said structural insert is a polymer film.

8. The system for magnetically attaching photovoltaic modules enabling enhanced redeployment according to claim 7 wherein said polymer film is reinforced with a fabric.

9. The system for magnetically attaching photovoltaic modules enabling enhanced redeployment according to claim 5 wherein said insert is a polymer support mount.

10. The system for magnetically attaching photovoltaic modules enabling enhanced redeployment according to claim 9 wherein said polymer support mount is substantially solid.

11. The system for magnetically attaching photovoltaic modules enabling enhanced redeployment according to claim 9 wherein said polymer support is substantially open to provide an airflow therein.

12. The system for magnetically attaching photovoltaic modules enabling enhanced redeployment according to claim 1 further comprising an air seal applied to a perimeter of said photovoltaic module and a substrate to prevent air from entering therein.

13. The system for magnetically attaching photovoltaic modules enabling enhanced redeployment according to claim 1 further comprising an adhesive member bounding at least a portion of a perimeter of said photovoltaic module wherein said photovoltaic module is sealed against a substrate.

14. The system for magnetically attaching photovoltaic modules enabling enhanced redeployment according to claim 1 further comprising a power distribution network operatively connected to said photovoltaic module.

15. The system for magnetically attaching photovoltaic modules enabling enhanced redeployment according to claim 1 wherein said magnetic membrane is a high-energy magnetic membrane.

16. The system for magnetically attaching photovoltaic modules enabling enhanced redeployment according to claim 1 wherein said magnetic membrane has an adhesive surface.

17. The system for magnetically attaching photovoltaic modules enabling enhanced redeployment according to claim 1 wherein said second surface is an adhesive surface.

18. The system for magnetically attaching photovoltaic modules enabling enhanced redeployment according to claim 2 wherein said insert has an adhesive on at least one surface therein.

19. A method for magnetically attaching photovoltaic modules enabling enhanced redeployment comprising the steps of:
obtaining at least one photovoltaic module with a magnetic membrane disposed along a lower surface of said at least one photovoltaic module; and
applying said at least one photovoltaic module to a magnetically receptive surface.

20. The method for magnetically attaching photovoltaic modules enabling enhanced redeployment according to claim 15 further comprising the steps of:
applying a magnetically receptive sheet to a substrate creating said magnetically receptive surface; and
applying a low surface energy adhesive tape around at least a portion of a perimeter of said photovoltaic module.
